(19) United States
(12) Patent Application Publication
(10) Pub. No.: US 2026/0127802 A1
(43) Pub. Date: May 7, 2026

(54) VIRTUAL AVATAR EVOLUTION SYSTEM BASED ON AI LEARNING AND OBSERVATION AND METHOD THEREOF

(71) Applicants: SQ Technology (Shanghai) Corporation, Shanghai (CN); Inventec Corporation, Taipei (TW)

(72) Inventors: Chuan-Cheng CHIU, Taipei (TW); Ta-Wei YEN, Taipei (TW); Qiu-Long JIANG, Shanghai (CN)

(73) Assignees: SQ Technology (Shanghai) Corporation, Shanghai (CN); Inventec Corporation, Taipei (TW)

(21) Appl. No.: 19/021,142

(22) Filed: Jan. 14, 2025

(30) Foreign Application Priority Data
Nov. 1, 2024 (CN) 2024115575166

(51) Int. Cl. G06T 13/40; G06N 3/0985; G10L 15/26

(52) U.S. Cl. CPC G06T 13/40; G06N 3/0985; G10L 15/26

(57) ABSTRACT

A virtual avatar evolution system based on AI learning and observation and a method thereof are disclosed. In the system, when a virtual avatar triggers an conversation event, speech of the virtual avatar is continuously recorded to generate a complete conversational speech, and the complete conversational speech is converted into a complete conversation message via a speech-to-text technology, then the complete conversation message is used as new training data for re-training a pre-trained language model; the complete conversation message is input into the personality analysis model to obtain real-person personality data, and the virtual personality data of the virtual avatar is dynamically adjusted based on the real-person personality data, thereby achieving the technical effect of enhancing the interaction compatibility of the virtual avatar.

### BACKGROUND OF THE INVENTION

### 1. Field of the Invention

The present invention relates to an evolution system and a method thereof, and more particularly to a virtual avatar evolution system based on AI learning and observation and a method thereof.

### 2. Description of the Related Art

In recent years, with the widespread and rapid development of virtual technology, various related applications have emerged in great numbers. Among these applications, a virtual avatar is the most common.

Generally, an existing virtual avatar typically interacts with a user using fixed behavior patterns, for example, conversation messages of the virtual avatar are pre-set. When a user interacts with a virtual avatar, the virtual avatar responds based on the pre-configured conversation messages, such as the behavior of non-player characters (NPCs) in games. However, while the existing method allows interaction with users, it often results in a rigid interaction manner and fails to provide the users with a satisfactory interaction experience. Thus, the existing virtual avatar suffers from insufficient interactivity.

For this reason, some companies have proposed a method of incorporating natural language processing techniques to generate natural language through understanding, to make the dialog of a virtual avatar no longer rigid. However, while this method allows a virtual avatar to avoid repetitive dialog, it may fail to resonate with the user, for example, in a condition that a user is introverted but the virtual avatar's dialog is highly extroverted, the virtual avatar may make user feel uneasy or uncomfortable. Conversely, when a user is extroverted, but the virtual avatar behaves very introverted, it can also make the user feel uncomfortable. Therefore, this method may reduce the willingness for interaction or communication due to personality differences between the user and the virtual avatar. In other words, this method has the problem of poor interaction compatibility with between a user and a virtual avatar.

According to above-mentioned contents, what is needed is to develop an improved solution to solve the problem of poor interaction compatibility with a user and a virtual avatar.

### SUMMARY OF THE INVENTION

An objective of the present invention is to disclose a virtual avatar evolution system based on AI learning and observation and a method thereof, to solve the problem of poor interaction compatibility with a user and a virtual avatar.

To achieve the objective, the present invention discloses a virtual avatar evolution system based on AI learning and observation, the system includes a non-transitory computer-readable storage medium and a hardware processor. The non-transitory computer-readable storage medium is configured to store computer readable instruction, a personality analysis model, a virtual personality data and a language model corresponding to a virtual avatar, wherein the personality analysis model and the language model are pre-trained machine learning models. The hardware processor is electrically connected to the non-transitory computer-readable storage medium, and configured to execute the computer readable instructions to perform operations of: loading the personality analysis model, the virtual personality data and the language model corresponding to the virtual avatar; when detecting that the virtual avatar triggers a conversation event, continuously recording speech of the virtual avatar to generate complete conversational speech, and converting the complete conversational speech into a complete conversation message through a speech-to-text technology; using the complete conversation message as new training data, and inputting the new training data into the pre-trained language model for retraining the language model; inputting the complete conversation message into the personality analysis model to output real-person personality data, and dynamically adjusting the virtual personality data of the virtual avatar based on the real-person personality data.

To achieve the objective, the present invention discloses a virtual avatar evolution method based on AI learning and observation, the virtual avatar evolution method is executed by a hardware processor and includes steps of: loading a personality analysis model, a virtual personality data and a language model corresponding to a virtual avatar, wherein the personality analysis model and the language model are pre-trained machine learning models; when detecting that the virtual avatar triggers a conversation event, continuously recording speech of the virtual avatar to generate a complete conversational speech, and converting the complete conversational speech into a complete conversation message through a speech-to-text technology; using the complete conversation message as new training data, and inputting the new training data into the pre-trained language model to retrain the language model; inputting the complete conversation message to the personality analysis model to output real-person personality data, and dynamically adjusting the virtual personality data of the virtual avatar based on the real-person personality data.

According to the above-mentioned system and method of the present invention, the difference between the present invention and conventional technology is that, in the present invention, when the virtual avatar triggers the conversation event, the speech of the virtual avatar is continuously recorded to generate the complete conversational speech, and the complete conversational speech is converted into the complete conversation message via the speech-to-text technology, then the complete conversation message is used as new training data for re-training the pre-trained language model; the complete conversation message is input into the personality analysis model to obtain real-person personality data, and the virtual personality data of the virtual avatar is dynamically adjusted based on the real-person personality data.

Therefore, the technical solution of the present invention can achieve the technical effect of enhancing the interaction compatibility of the virtual avatar.

### BRIEF DESCRIPTION OF THE DRAWINGS

The structure, operating principle and effects of the present invention will be described in detail by way of various embodiments which are illustrated in the accompanying drawings.

FIG. 1 is a block diagram of a virtual avatar evolution system based on AI learning and observation, according to the present invention.

FIG. 2 is a flowchart of a virtual avatar evolution method based on AI learning and observation, according to the present invention.

FIG. 3 is a schematic view of adjusting interaction personality of a virtual avatar, according to an application of the present invention.

FIG. 4 is a schematic view of adjust virtual personality data, according to an application of the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims.

These embodiments are provided so that this disclosure is thorough and complete, and fully conveys the inventive concept to those skilled in the art. Regarding the drawings, the relative proportions, and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise. As used herein, the term “or” includes any and all combinations of one or more of the associated listed items.

It will be acknowledged that when an element or layer is referred to as being “on”, “connected to” or “coupled to” another element or layer, it can be directly on, connected or coupled to the other element or layer, or intervening elements or layers may be present. In contrast, when an element is referred to as being “directly on”, “directly connected to” or “directly coupled to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

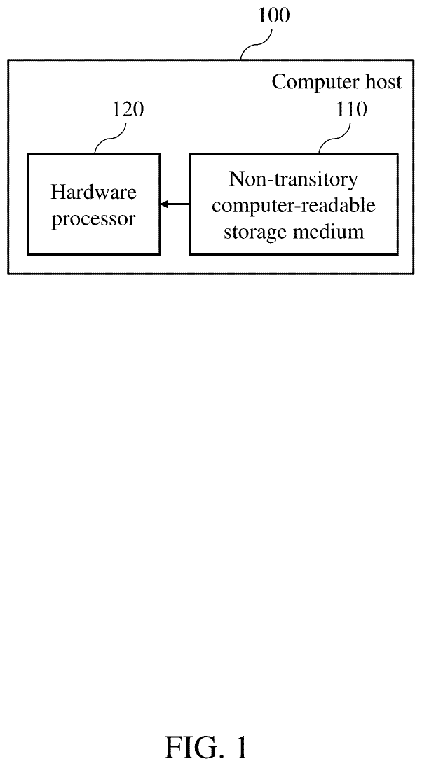

Please refer to FIG. 1. FIG. 1 is a block diagram of a virtual avatar evolution system based on AI learning and observation, according to the present invention. The virtual avatar evolution system includes a non-transitory computer-readable storage medium 110 and a hardware processor 120 which are disposed in a computer host 100. The non-transitory computer-readable storage medium 110 is configured to store computer readable instructions, a personality analysis model, and a virtual personality data and a language model corresponding to a virtual avatar. The personality analysis model and the language model are pre-trained machine learning model. In actual implementation, the non-transitory computer-readable storage medium 110 may include a hard disk, an optical disk, a flash memory, or the like. The computer readable instructions can be executed by the hardware processor 120. The computer readable instructions can be assembly language instructions, instruction-set-structure instructions, machine instructions, machine-related Instructions, micro-instructions, firmware instructions, or source codes or object codes written in any combination of one or more programming languages. The programming language includes object-oriented programming languages, such as: Common Lisp, Python, C++, Objective-C, Smalltalk, Delphi, Java, Swift, C#, Perl, Ruby, or PHP; the programming language can include regular procedural programming languages, such as C language or similar programming languages. It is to be specifically noted that, the virtual personality data can be stored in structured file format (e.g., JSON, XML, etc.) and used as the basis for the personality expression of the virtual avatar.

The hardware processor 120 is electrically connected to the non-transitory computer-readable storage medium 110 and configured to execute the computer readable instructions to perform the following operations. Initially, the personality analysis model, the virtual personality data and the language model corresponding to the virtual avatar are loaded. When detecting that the virtual avatar triggers a conversation event, the hardware processor 120 continuously records speech of the virtual avatar to generate complete conversational speech and converts the complete conversational speech into a complete conversation message through a speech-to-text technology. The hardware processor 120 uses the complete conversation message as new training data and inputs the new training data into the pre-trained language model for retraining the language model. The hardware processor 120 inputs the complete conversation message into the personality analysis model to output real-person personality data, and dynamically adjusts the virtual personality data of the virtual avatar based on the real-person personality data. In practical implementation, the language model can be re-trained through fine-tuning technology in which new training data is preprocessed (e.g., noise removal, standardization, regularization, etc.), hyperparameters are set for fine-tuning to re-train the language mode. In an embodiment, the hyperparameters at least include a learning rate and a batch size. Moreover, the language model can be retrained using incremental learning technology in which the language model is adjusted based on the new training data and a gradient descent algorithm, and a memory-augmented neural network is used to store history learning content during training, to prevent the language model from forgetting past learning content. Additionally, the personality analysis model can include a support vector machine, a decision tree, and a deep learning model for characteristic extraction and classification, the personality analysis model is configured to infer personality characteristics based on the complete conversation message to output the personality characteristics as the real-person personality data; furthermore, the personality analysis model allows reception of a feedback opinion (e.g., through questions, surveys, etc.) to adjust the weights thereof as a basis for optimization. It should be noted that the real-person personality data and the virtual personality data can include characteristic parameters including a personality characteristic (e.g., extroverted, introverted, etc.), a conversational style (e.g., humorous, cold, etc.), a decision mode (e.g., cooperative, adventurous, etc.), and an interaction manner (e.g., proactive, attentive, etc.). Each of the characteristic parameters corresponding to a characteristic weight. One of linear weighting adjustment, adaptive adjustment, weighted average, or direct replacement can be used to dynamically adjust the virtual personality data of the virtual avatar. Similarly, the real-person personality data can also be stored using the structured file format.

It is to be particularly noted that, in actual implementation, the above-mentioned solution of the present invention can be implemented fully or partly based on hardware, for example, the hardware processor 120 of the system can be implemented by integrated circuit chip, system on chip (SoC), a complex programmable logic device (CPLD), or a field programmable gate array (FPGA). The non-transitory computer-readable storage medium 110 of the present invention records computer readable program instructions, and the hardware processor 122 can execute the computer readable program instructions to implement concepts of the present invention. The non-transitory computer-readable storage medium 110 can be a tangible apparatus for holding and storing the instructions executable of an instruction executing apparatus. The non-transitory computer-readable storage medium 110 can be, but not limited to electronic storage apparatus, magnetic storage apparatus, optical storage apparatus, electromagnetic storage apparatus, semiconductor storage apparatus, or any appropriate combination thereof. More particularly, the non-transitory computer-readable storage medium 110 can include a hard disk, an RAM memory, a read-only-memory, a flash memory, an optical disk, a floppy disc, or any appropriate combination thereof, but this exemplary list is not an exhaustive list. The non-transitory computer-readable storage medium 110 is not interpreted as the instantaneous signal such a radio wave or other freely propagating electromagnetic wave, or electromagnetic wave propagated through waveguide, or other transmission medium (such as optical signal transmitted through fiber cable), or electric signal transmitted through electric wire. Furthermore, the computer readable program instruction can be downloaded from the non-transitory computer-readable storage medium 110 to each calculating/processing apparatus, or downloaded through network, such as internet network, local area network, wide area network and/or wireless network, to external computer equipment or external storage apparatus. The network includes copper transmission cable, fiber transmission, wireless transmission, router, firewall, switch, hub and/or gateway. The network card or network interface of each calculating/processing apparatus can receive the computer readable program instructions from network and forward the computer readable program instruction to store in non-transitory computer-readable storage medium 110 of each calculating/processing apparatus.

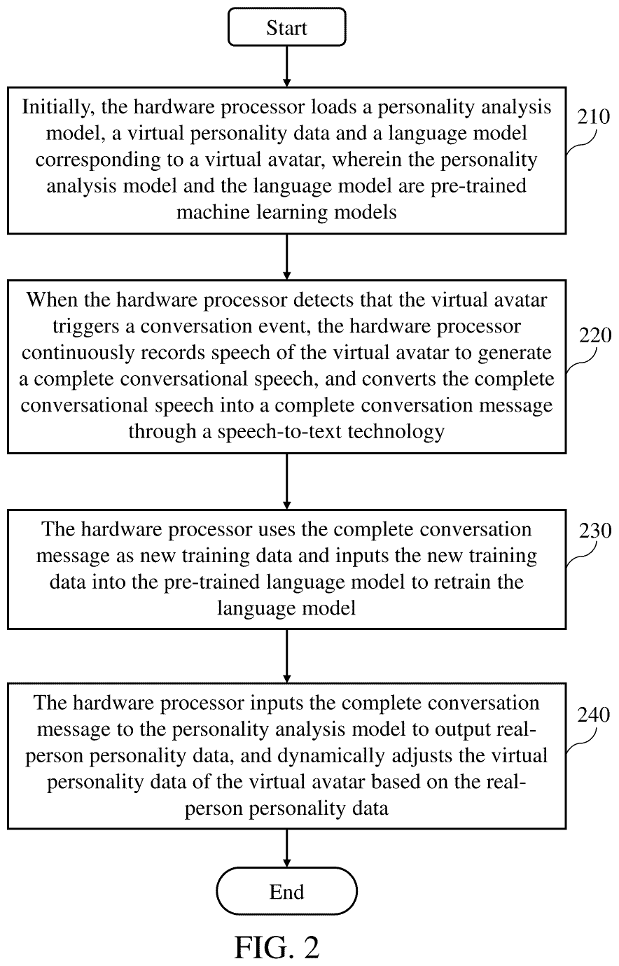

Please refer to FIG. 2. FIG. 2 is a flowchart of a virtual avatar evolution method based on AI learning and observation, according to the present invention. The virtual avatar evolution method is executed by a hardware processor 120 and includes following steps. In a step 210, initially, the hardware processor 120 loads a personality analysis model, a virtual personality data and a language model corresponding to a virtual avatar, wherein the personality analysis model and the language model are pre-trained machine learning models. In a step 220, when the hardware processor 120 detects that the virtual avatar triggers a conversation event, the hardware processor 120 continuously records speech of the virtual avatar to generate a complete conversational speech, and converts the complete conversational speech into a complete conversation message through a speech-to-text technology. In a step 230, the hardware processor 120 uses the complete conversation message as new training data and inputs the new training data into the pre-trained language model to retrain the language model. In a step 240, the hardware processor 120 inputs the complete conversation message to the personality analysis model to output real-person personality data, and dynamically adjusts the virtual personality data of the virtual avatar based on the real-person personality data. Through aforementioned steps, when the virtual avatar triggers the conversation event, speech of the virtual avatar is continuously recorded to generate the complete conversational speech, and the complete conversational speech is converted into the complete conversation message via the speech-to-text technology, then the complete conversation message is used as new training data for re-training the pre-trained language model; the complete conversation message is input into the personality analysis model to obtain real-person personality data, and the virtual personality data of the virtual avatar can be dynamically adjusted based on the real-person personality data.

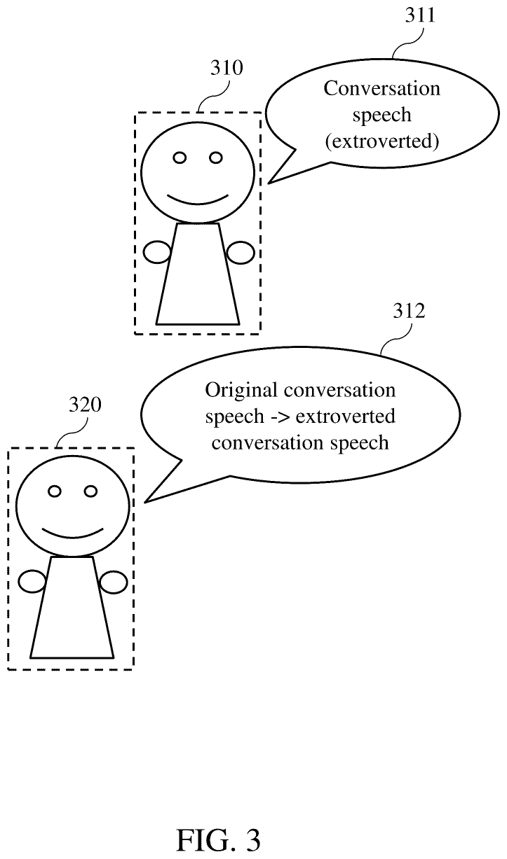

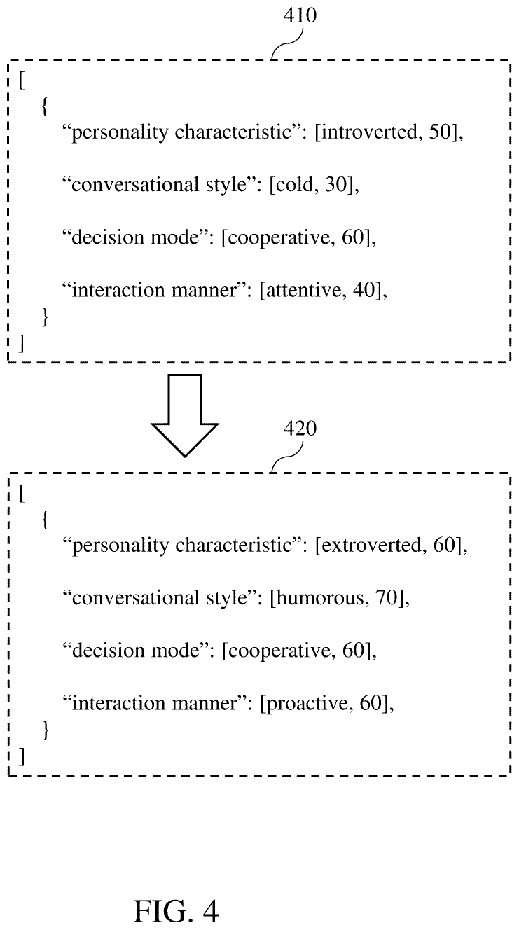

An embodiment of the present invention will be illustrated in the following paragraphs with reference to FIG. 3 and FIG. 4. Please refer to FIG. 3. FIG. 3 is a schematic view of adjusting interaction personality of a virtual avatar, according to an application of the present invention. When a user 310 engages in a conversation with a virtual avatar 320, the hardware processor 120 detects that the virtual avatar 320 triggers a conversation event, at this point, the hardware processor 120 continuously records the conversation between the virtual avatar 320 and the user 310 to generate complete conversational speech. Subsequently, the hardware processor 120 converts the complete conversational speech into a text-based complete conversation message through a speech-to-text technology. Next, the hardware processor 120 uses the complete conversation message as new training data, and then input the new training data into the pre-trained language model to retrain the language model. Moreover, the hardware processor 120 also inputs the complete conversation message into a personality analysis model to output real-person personality data, and then dynamically adjust the virtual personality data of the virtual avatar 320 based on the real-person personality data. At this stage, the language model has been retrained and the virtual personality data has been dynamically adjusted, so that the sentences used by the virtual avatar 320 during the conversation can be aligned with the user due to the retrained language model and the personality expressed by the virtual avatar 320 can be aligned with the user due to the adjusted virtual personality data. As shown in FIG. 3, the conversation content of a user 310 is represented by a conversation block 311, the conversation content of a virtual avatar 320 is represented by a conversation block 312, for example, in a condition that the conversational speech of the user 310 indicates an extroverted tendency, the virtual avatar 320 initially converses using its original sentences and virtual personality data. Once the language model is re-trained and the virtual personality data is re-adjusted, the virtual avatar 320 transitions from its original conversational speech to an extroverted conversational speech. At this point, the word choice, tone, and personality expression of the virtual avatar 320 closely resemble those of the user 310, so the user 310 can feel a strong sense of compatibility, thereby effectively enhancing the interaction compatibility between the user 310 and the virtual avatar 320.

Please refer to FIG. 4. FIG. 4 is a schematic view of adjusting virtual personality data, according to an application of the present invention. In practical implementation, the personality expression of the virtual avatar is controlled by the virtual personality data. For example, when the personality characteristic of original virtual personality data 410 is introverted, its corresponding characteristic weight is set to 50; when the conversational style is cold, its corresponding characteristic weight is set to 30; when the decision mode is cooperative, the corresponding characteristic weight is set to 60; when the interaction manner is attentive, the corresponding characteristic weight is set to 40. Therefore, when an extroverted user interacts with the virtual avatar, the resulting complete conversation message is not only used as new training data to retrain language model but also input into the personality analysis model to output real-person personality data, thereby adjusting the virtual personality data of the virtual avatar based on the real-person personality data. The simplest adjustment method is direct replacement, which makes the virtual personality data the same as the real-person personality data, but this method lacks diversity and may led to a sense of similarity repulsion. In practical implementation, alternative methods for adjusting weights can include linear weighting adjustment, adaptive adjustment, or weighted average, these methods make the weights of the virtual personality data and the real-person personality data be similar but not identical. For example, in the example shown in FIG. 3, the adjusted virtual personality data 420 is changed as follows: the personality characteristic transitions from introverted to extroverted, the conversational style transitions from cold to humorous, and the interaction manner transitions from attentive to proactive. In an embodiment, the characteristic weight values determine these transitions. For the personality characteristic, the characteristic weight higher than 50 indicates extroverted, and the characteristic weight not higher than 50 indicates introverted. For the conversational style, the characteristic weight higher than 50 indicates a humorous characteristic, and the characteristic weight not higher than 50 indicates cold a characteristic. For the decision mode, the characteristic weight higher than 50 indicates a cooperative characteristic, and the characteristic weight not higher than 50 indicates an adventurous characteristic. For the interaction manner, the characteristic weight higher than 50 indicates a proactive characteristic, and the characteristic weight not higher than 50 indicates an attentive characteristic. It is to be specifically noted that the characteristic weights are used in the present invention for explaining these examples, but the present invention is not limited thereto. Any numerical representation capable of distinguishing different personalities falls within the application field of the present invention.

According to above-mentioned contents, the difference between the present invention and the conventional technology is that, in the present invention, when the virtual avatar triggers the conversation event, the speech of the virtual avatar is continuously recorded to generate the complete conversational speech, and the complete conversational speech is converted into the complete conversation message via the speech-to-text technology, then the complete conversation message is used as new training data for re-training the pre-trained language model; the complete conversation message is input into the personality analysis model to obtain real-person personality data, and the virtual personality data of the virtual avatar is dynamically adjusted based on the real-person personality data. Therefore, the technical solution of the present invention can solve the conventional problem and achieve the technical effect of enhancing the interaction compatibility of the virtual avatar.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A virtual avatar evolution system based on AI learning and observation, comprising:
a non-transitory computer-readable storage medium, configured to store computer readable instruction, a personality analysis model, a virtual personality data and a language model corresponding to a virtual avatar, wherein the personality analysis model and the language model are pre-trained machine learning models; and
a hardware processor, electrically connected to the non-transitory computer-readable storage medium, and configured to execute the computer readable instructions to operate:
loading the personality analysis model, the virtual personality data and the language model corresponding to the virtual avatar;
when detecting that the virtual avatar triggers a conversation event, continuously recording speech of the virtual avatar to generate complete conversational speech, and converting the complete conversational speech into a complete conversation message through a speech-to-text technology;
using the complete conversation message as new training data, and inputting the new training data into the pre-trained language model for retraining the language model; and
inputting the complete conversation message into the personality analysis model to output real-person personality data, and dynamically adjusting the virtual personality data of the virtual avatar based on the real-person personality data.

2. The virtual avatar evolution system based on AI learning and observation according to claim 1, wherein the language model is re-trained through a fine-tuning technology, the new training data is pre-processed, hyperparameters are then set for fine-tuning for retraining the language model, wherein the hyperparameters at least comprise a learning rate and a batch size.

3. The virtual avatar evolution system based on AI learning and observation according to claim 1, wherein the language model is retrained through incremental learning technology in which the language model is adjusted based on the new training data and a gradient descent algorithm, and a memory-augmented neural network is used to store history learning content during training to prevent the language model from forgetting past learning content.

4. The virtual avatar evolution system based on AI learning and observation according to claim 1, wherein the personality analysis model comprises a support vector machine, a decision tree, and a deep learning model for characteristic extraction and classification, the personality analysis model is configured to infer personality characteristics based on the complete conversation message to output the personality characteristics as the real-person personality data, and the personality analysis model allows receiving at least one feedback opinion to adjust weights thereof as a basis for optimization.

5. The virtual avatar evolution system based on AI learning and observation according to claim 1, wherein each of the real-person personality data and the virtual personality data comprises characteristic parameters having a personality characteristic, a conversational style, a decision mode, and a interaction manner, each of the characteristic parameters corresponding to a characteristic weight, and one of linear weighting adjustment, adaptive adjustment, weighted average, or direct replacement is used to dynamically adjust the virtual personality data of the virtual avatar based on the real-person personality data.

6. A virtual avatar evolution method based on AI learning and observation, wherein the virtual avatar evolution method is executed by a hardware processor and comprises:
loading a personality analysis model, a virtual personality data and a language model corresponding to a virtual avatar, wherein the personality analysis model and the language model are pre-trained machine learning models;
when detecting that the virtual avatar triggers a conversation event, continuously recording speech of the virtual avatar to generate a complete conversational speech, and converting the complete conversational speech into a complete conversation message through a speech-to-text technology;
using the complete conversation message as new training data, and inputting the new training data into the pre-trained language model to retrain the language model; and
inputting the complete conversation message to the personality analysis model to output real-person personality data, and dynamically adjusting the virtual personality data of the virtual avatar based on the real-person personality data.

7. The virtual avatar evolution method based on AI learning and observation according to claim 6, wherein the language model is re-trained through a fine-tuning technology, the new training data is pre-processed, hyperparameters are then set for fine-tuning for retraining the language model, wherein the hyperparameters at least comprise a learning rate and a batch size.

8. The virtual avatar evolution method based on AI learning and observation according to claim 6, wherein the language model is retrained through incremental learning technology in which the language model is adjusted based on the new training data and a gradient descent algorithm, and a memory-augmented neural network is used to store history learning content during training to prevent the language model from forgetting past learning content.

9. The virtual avatar evolution method based on AI learning and observation according to claim 6, wherein the personality analysis model comprises a support vector machine, a decision tree, and a deep learning model for characteristic extraction and classification, the personality analysis model is configured to infer personality characteristics based on the complete conversation message to output the personality characteristics as the real-person personality data, and the personality analysis model allows receiving at least one feedback opinion to adjust weights thereof as a basis for optimization.

10. The virtual avatar evolution method based on AI learning and observation according to claim 6, wherein each of the real-person personality data and the virtual personality data comprises characteristic parameters having a personality characteristic, a conversational style, a decision mode, and a interaction manner, each of the characteristic parameters corresponding to a characteristic weight, and one of linear weighting adjustment, adaptive adjustment, weighted average, or direct replacement is used to dynamically adjust the virtual personality data of the virtual avatar based on the real-person personality data.
